(19) United States
(12) Patent Application Publication
(10) Pub. No.: US 2021/0381386 A1
(43) Pub. Date: Dec. 9, 2021

(54) OXIDE LAYER COMPOSITIONS FOR TURBINE ENGINE COMPONENTS

(71) Applicant: Applied Materials, Inc., Santa Clara, CA (US)

(72) Inventors: Nitin DEEPAK, Mumbai (IN); Sarin Sundar JAINNAGAR KUPPUSWAMY, Hyderabad (IN); Prerna Sonthalia GORADIA, Mumbai (IN); Sukti CHATTERJEE, San Jose, CA (US); Lance A. SCUDDER, Sunnyvale, CA (US); Kenichi OHNO, Sunnyvale, CA (US); Yuriy MELNIK, San Jose, CA (US); David Alexander BRITZ, San Jose, CA (US); Sankalp PATIL, Bangalore (IN); Ankur KADAM, Mumbai (IN); Abhishek MANDAL, Maharashtra (IN)

(21) Appl. No.: 16/897,144

(22) Filed: Jun. 9, 2020

(51) Int. Cl. F01D 5/28; C23C 16/40; C23C 16/06; C23C 16/455; C23C 14/08; C23C 14/14

(52) U.S. Cl. CPC F01D 5/282; C23C 16/403; C23C 16/06; F05B 2280/10741; C23C 14/081; C23C 14/14; F05B 2280/1071; C23C 16/45525

(57) ABSTRACT

Embodiments of the present disclosure generally relate to oxide layer compositions for turbine engine components and methods for depositing the oxide layer compositions. In one or more embodiments, a turbine engine component includes a superalloy substrate and a bond coat disposed over the superalloy substrate. The turbine engine component includes an oxide layer disposed over the bond coat, where the oxide layer includes aluminum oxide and a metal dopant. The turbine engine component includes a thermal barrier coating disposed over the oxide layer.

### BACKGROUND

### Field

Embodiments of the present disclosure generally relate to oxide layer compositions for turbine engine components and methods for coating turbine engine components, and in particular to oxide layer compositions containing Al₂O₃, and optionally metal dopants, and methods for depositing the oxide layer compositions.

### Description of the Related Art

Turbine engines (e.g., gas turbines and jet engine systems) typically have components which corrode or degrade over time from exposure to hot gases and/or reactive chemicals (e.g., acids, bases, or salts). Such turbine engine components (e.g., turbine blades, turbine disks, nozzle guide vanes, combustor liners, buckets, rotors, and/or stators) are often protected by a thermal and/or chemical barrier coating bonded to a superalloy substrate by a bond coat. Thermal barrier coatings (TBCs) help protect superalloy substrates of turbine engine components from heat damage by shielding against high temperatures. However, TBCs can experience damage and/or failure at extreme operating temperatures. In that regard, thermal insulating properties of TBCs are reduced where damage and/or failure occurs leading to an increase in localized superalloy temperature, which may trigger destruction of turbine engine components and/or loss of entire turbine engines.

Recent growth in the need for turbine engines that offer greater operating efficiency has caused modification of some operating specifications with a resultant increase in inlet temperatures. Thus, operational modifications intended to improve efficiency have led to exposure of turbine engine components to even higher temperatures amplifying existing issues with TBCs, such as issues related to spalling. One primary cause of spalling is natural growth of a thermally grown oxide (TGO) layer at an interface of the bond coat and the TBC due to high-temperature oxidation which can occur in air or reduced oxygen. Another cause of spalling is poor adhesion between the bond coat and the TBC. The TGO can contain metal oxides such as nickel oxide, tantalum oxide, cobalt oxide, chromium oxide, or combinations thereof, which can accelerate TGO growth. When the TGO layer grows too quickly, underlying strain can contribute to spalling of the overlying TBC. Therefore, slowing TGO layer growth can reduce and/or prevent TBC spalling damage.

Therefore, oxide layer compositions for turbine engine components and methods for depositing the oxide layer compositions are needed to reduce native oxide growth and/or to improve adhesion between bond coats and TBCs.

### SUMMARY

Embodiments of the present disclosure generally relate to oxide layer compositions for turbine engine components and methods for depositing the oxide layer compositions.

In one or more embodiments, a turbine engine component is provided and includes a superalloy substrate, a bond coat disposed over the superalloy substrate, an oxide layer disposed over the bond coat, and a thermal barrier coating disposed over the oxide layer. The oxide layer contains aluminum oxide and a metal dopant.

In some embodiments, a method for coating the superalloy substrate of a turbine engine component is provided and includes forming the bond coat over the superalloy substrate, depositing the oxide layer over the bond coat using at least one of chemical vapor deposition (CVD), physical vapor deposition (PVD), atomic layer deposition (ALD), or combinations thereof, and forming a thermal barrier coating over the oxide layer.

In one or more embodiments, a turbine engine component is provided and includes a superalloy substrate including at least one of a nickel-based superalloy, a cobalt-based superalloy, an iron-based superalloy, or a combination thereof. The turbine engine component includes a bond coat contacting the superalloy substrate. The bond coat includes at least one metal having the formula MCrAl(X). M is selected from the group consisting of Ni and Co, and X is selected from the group consisting of Hf, W, Zr, Y, and La. The turbine engine component includes an oxide layer contacting the bond coat. The oxide layer contains aluminum oxide and a metal dopant. The oxide layer includes about 95 wt % or greater of the aluminum oxide, based on total weight of the oxide layer. The metal dopant is selected from the group consisting of Hf, Y, La, Ce, Cr, Nd, Dy, Yb, Sr, Ba, Lu, Ho, Gd, Er, Ti, Nb, Sm, Tb, and Tm. The turbine engine component includes a thermal barrier coating contacting the oxide layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a perspective view of a turbine engine according to an embodiment.

FIG. 2 is a flowchart illustrating a method for coating a turbine engine component according to an embodiment.

FIGS. 3A-3G are partial side sectional views of a turbine engine component at sequential fabrication steps of the method of FIG. 2 according to an embodiment.

To facilitate understanding, identical reference numerals have been used, where possible, to designate identical elements that are common to the Figures. It is contemplated that elements and features of one or more embodiments may be beneficially incorporated in other embodiments.

### DETAILED DESCRIPTION

Embodiments of the present disclosure generally relate to oxide layer compositions for turbine engine components and methods for depositing the oxide layer compositions. In some embodiments, oxide layer compositions and methods of the present disclosure may generally apply to high-temperature industrial uses (e.g., where temperatures may exceed 900° C.).

In some embodiments, the oxide layer compositions may protect turbine engine components from oxidation by reducing and/or slowing native oxide growth. In some embodiments, the oxide layer compositions may extend TBC lifetimes. In one or more embodiments, the oxide layer compositions may form an effective barrier against oxygen diffusion. In some embodiments, the oxide layer compositions may be chemically stable for improved bonding between bond coats and TBCs. In some embodiments, the oxide layer compositions may reduce and/or prevent TBC spelling. In some embodiments, the oxide layer compositions may allow turbine engine components to operate at higher than normal temperatures. In one or more embodiments, the oxide layer compositions do not affect weight, dimensional tolerances, low cycle fatigue life, and/or thermal conductivity of the turbine engine components.

### Turbine Engine Components

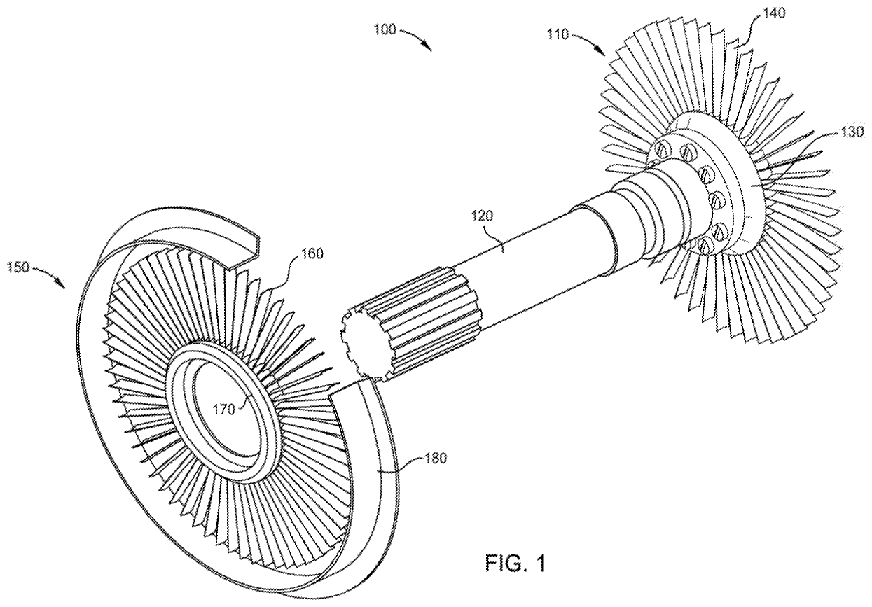

FIG. 1 is a perspective view of a turbine engine 100 according to an embodiment. The turbine engine 100 includes a turbine blade assembly 110 axially coupled to a turbine rotor 120 by a turbine disk 130. The turbine blade assembly 110 includes a plurality of turbine blades 140 radially attached to the turbine disk 130. In some embodiments, the plurality of turbine blades 140 can include from about 10 to about 200 blades. The turbine engine 100 further includes a nozzle assembly 150. The nozzle assembly 150 includes a plurality of nozzle guide vanes 160 radially attached to a central hub 170. The plurality of nozzle guide vanes 160 extend from the central hub 170 to a stator ring 180 circumferentially surrounding the plurality of nozzle guide vanes 160.

In some embodiments, turbine engine components as described and discussed herein can be or include one or more turbine blades (e.g., turbine blades 140), turbine disks (e.g., turbine disk 130), nozzle guide vanes (e.g., nozzle guide vanes 160), combustor liners, buckets, rotors (e.g., turbine rotor 120), stators (e.g., central hub 170 and stator ring 180), or combinations thereof. In some embodiments, turbine engine components as described and discussed herein can be or include one or more assemblies (e.g., turbine blade assembly 110 and nozzle assembly 150). In some embodiments, turbine engine components as described and discussed herein can be or include any other aerospace component or part that can benefit from having an oxide layer composition deposited thereon.

In some embodiments, the oxide layer compositions can be deposited or otherwise formed on interior surfaces and/or exterior surfaces of the turbine engine components. The interior surfaces can define one or more cavities extending or contained within the turbine engine components. The cavities can be channels, passages, spaces, or the like disposed between the interior surfaces. Each cavity can have one or more openings. Each cavity can have an aspect ratio (i.e., length divided by width) of greater than 1. The methods described and discussed herein provide depositing and/or otherwise forming the oxide layer compositions on interior surfaces with high aspect ratios (greater than 1) and/or within the cavities.

In some embodiments, a cavity can have an aspect ratio of from about 2, about 3, about 5, about 8, about 10, or about 12 to about 15, about 20, about 25, about 30, about 40, about 50, about 65, about 80, about 100, about 120, about 150, about 200, about 250, about 300, about 500, about 800, about 1,000, or greater. For example, the aspect ratio of a cavity can be from about 2 to about 1,000, about 2 to about 500, about 2 to about 200, about 2 to about 150, about 2 to about 120, about 2 to about 100, about 2 to about 80, about 2 to about 50, about 2 to about 40, about 2 to about 30, about 2 to about 20, about 2 to about 10, about 2 to about 8, about 5 to about 1,000, about 5 to about 500, about 5 to about 200, about 5 to about 150, about 5 to about 120, about 5 to about 100, about 5 to about 80, about 5 to about 50, about 5 to about 40, about 5 to about 30, about 5 to about 20, about 5 to about 10, about 5 to about 8, about 10 to about 1,000, about 10 to about 500, about 10 to about 200, about 10 to about 150, about 10 to about 120, about 10 to about 100, about 10 to about 80, about 10 to about 50, about 10 to about 40, about 10 to about 30, about 10 to about 20, about 20 to about 1,000, about 20 to about 500, about 20 to about 200, about 20 to about 150, about 20 to about 120, about 20 to about 100, about 20 to about 80, about 20 to about 50, about 20 to about 40, or about 20 to about 30.

In some embodiments, oxide layer compositions of the present disclosure may be applied to aerospace components, such as the turbine engine components listed above. In one or more other embodiments, aerospace components of the present disclosure can be or include one or more components or portions of a fuel system, an aircraft, or a spacecraft. In some other embodiments, oxide layer compositions of the present disclosure may be applied to other devices that can be or include one or more turbines (e.g., compressors, pumps, turbo fans, super chargers, and the like).

### Superalloy Substrates

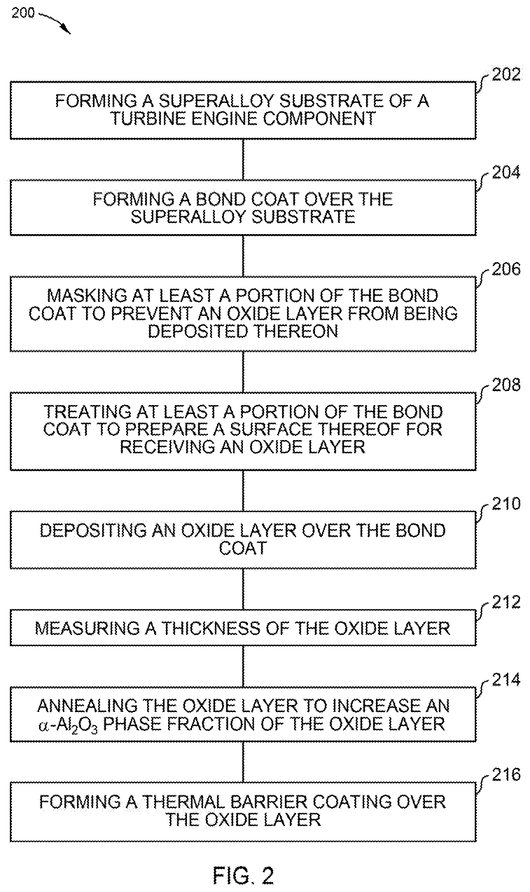

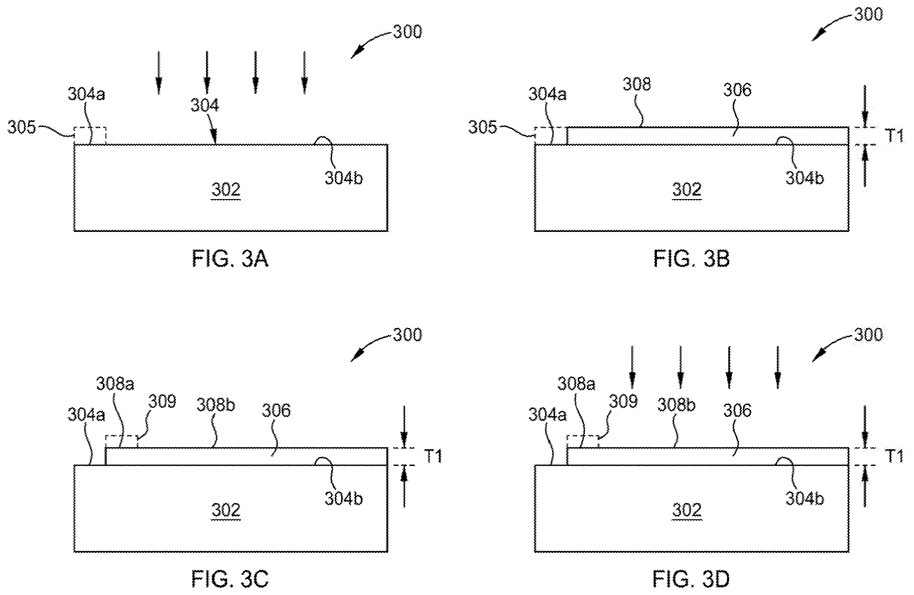

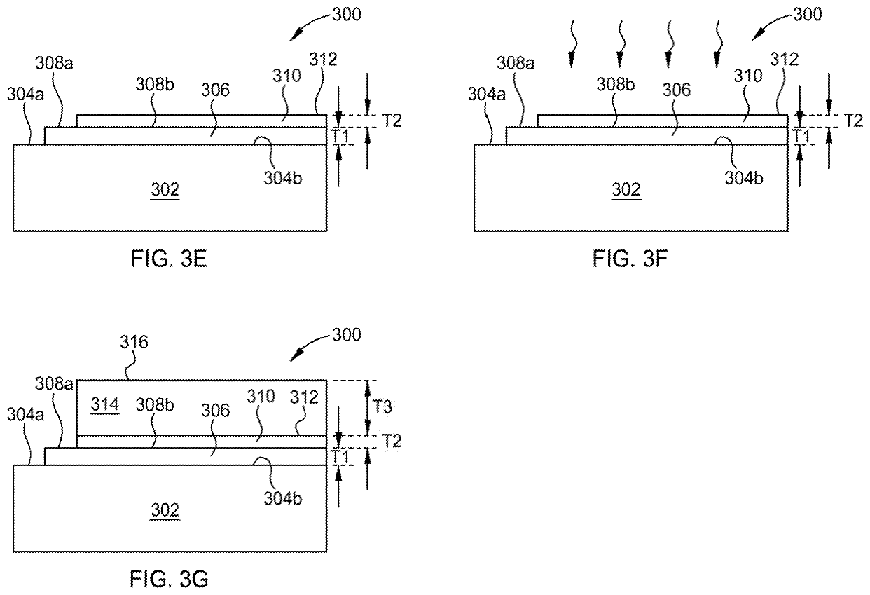

FIG. 2 is a flowchart illustrating a method 200 for coating a turbine engine component according to an embodiment. FIGS. 3A-3G are partial side sectional views of a turbine engine component 300 at sequential fabrication steps of the method 200 of FIG. 2 according to an embodiment.

Referring to FIGS. 2 and 3A, the method 200 begins at block 202 by forming a superalloy substrate 302 of the turbine engine component 300. In some embodiments, superalloys of the present disclosure can be cast into a rough cast shape and machined to form the superalloy substrate 302 having a surface 304. In one or more embodiments, cooling holes may be drilled in the machined superalloy substrate 302.

In some embodiments, superalloy substrates of the present disclosure can be based on nickel, cobalt, iron, or combinations thereof. In some embodiments, a nickel-based superalloy may contain one or more Haynes® series superalloys, one or more Hiperco® series superalloys, one or more Stellite™ series superalloys, or combinations thereof. In some embodiments, a cobalt-based superalloy may contain one or more Astroloy series superalloys. In some embodiments, an iron-based superalloy may contain one or more Hastelloy® series superalloys, one or more Rene® series superalloys, such as Rene 108 and other Rene superalloys, one or more Inconel® series superalloys, one or more Waspaloy series superalloys, one or more Monel® series superalloys, one or more Invar series superalloys, or combinations thereof. In some embodiments, superalloy substrates of the present disclosure can be or include one or more CMSX series superalloys, such as CMSX-2, CMSX-3, CMSX-4®, CMSX-4 Plus, CMSX-8, CMSX-10, CMSX-10K/N®, and other CMSX superalloys, one or more IN-100 series superalloys, one or more MAR M series superalloys, such as MAR M 002, MAR M 200, MAR M 247, and other MAR M series superalloys, or combinations thereof. In some embodiments, superalloy substrates of the present disclosure can be or include one or more metals, such as nickel, chromium, cobalt, chromium-cobalt alloys, molybdenum, iron, titanium, one or more Cannon-Muskegon alloys, one or more PWA alloys, or combinations thereof. In some embodiments, superalloy substrates of the present disclosure can be or include one or more single crystal superalloys, one or more directionally solidified casting nickel-based superalloys, or combinations thereof.

In some embodiments, a mask 305 may be applied to a first portion 304a of the surface 304 to prevent a bond coat 306 from being formed on the first portion 304a. In some embodiments, the mask 305 may be applied using chemical vapor deposition (CVD), physical vapor deposition (PVD), electron beam PVD (EBPVD), or combinations thereof. In some embodiments, the mask 305 may be continuous and/or crack-free to block a gas phase of the bond coat 306 from reaching the first portion 304a. In some embodiments, the mask 305 can be or include titanium nitride, zirconium nitride, hafnium nitride, calcium fluoride, strontium fluoride, barium fluoride, aluminum nitride, scandium oxide, zirconium oxide, hafnium oxide, other ceramic materials, other suitable materials, or combinations thereof. In some embodiments, the mask material may be stable at temperatures used for forming the bond coat 306. In some embodiments, the mask material may not react with either the surface 304 or the gas phase of the bond coat 306. In some embodiments, the mask 305 can be removed using mechanical abrasion (e.g., grit blasting) and/or chemical cleaning.

In some embodiments, a second portion 304b of the surface 304 may be treated to prepare the second portion 304b for receiving a bond coat 306. In some embodiments, the first and second portions 304a, 304b may be different portions of the surface 304. In some embodiments, the first and second portions 304a, 304b may overlap. In some embodiments, the surface 304 may be treated before the first portion 304a is masked. In some embodiments, only the second portion 304b may be treated after the first portion 304a is masked. In some embodiments, the surface 304 and/or the second portion 304b may be treated using wet cleaning, dry cleaning, oxide etching, grit blasting, polishing, or combinations thereof.

### Clean Process

The turbine engine component 300, including the superalloy substrate 302, can optionally be exposed to one or more cleaning processes. One or more contaminants are removed from the turbine engine component 300 to produce the cleaned surface during the cleaning process. The contaminant can be or include oxides, organics or organic residues, carbon, oil, soil, particulates, debris, and/or other contaminants, or any combination thereof. These contaminants are removed prior to coating the turbine engine component 300.

The cleaning process can be or include one or more basting or texturing processes, vacuum purges, solvent clean, acid clean, basic or caustic clean, wet clean, ozone clean, plasma clean, sonication, or any combination thereof. Once cleaned and/or textured, subsequently deposited layers have stronger adhesion to the cleaned surfaces or otherwise altered surfaces of the turbine engine component 300 than if otherwise not exposed to the cleaning process.

In one or more examples, the surfaces of the turbine engine component 300 can be blasted with or otherwise exposed to beads, sand, carbonate, or other particulates to remove oxides and other contaminates therefrom and/or to provide texturing to the surfaces of the turbine engine component 300. In some examples, the turbine engine component 300 can be placed into a chamber within a pulsed push-pull system and exposed to cycles of purge gas or liquid (e.g., N₂, Ar, He, one or more alcohols (methanol, ethanol, propanol, and/or others), H₂O, or any combination thereof) and vacuum purges to remove debris from small holes on the turbine engine component 300. In other examples, the surfaces of the turbine engine component 300 can be exposed to hydrogen plasma, oxygen or ozone plasma, and/or nitrogen plasma, which can be generated in a plasma chamber or by a remote plasma system.

In some examples, such as for organic removal or oxide removal, the surfaces of the turbine engine component 300 can be exposed to a hydrogen plasma, then degassed, then exposed to ozone treatment. In other examples, such as for organic removal, the surfaces of the turbine engine component 300 can be exposed to a wet clean that includes: soaking in an alkaline degreasing solution, rinsing, exposing the surfaces to an acid clean (e.g., sulfuric acid, phosphoric acid, hydrochloric acid, hydrofluoric acid, or any combination thereof), rinsing, and exposing the surfaces to a deionized water sonication bath. In some examples, such as for oxide removal, the surfaces of the turbine engine component 300 can be exposed to a wet clean that includes: exposing the surfaces to a dilute acid solution (e.g., acetic acid hydrochloric acid, hydrofluoric acid, or combinations thereof), rinsing, and exposing the surfaces to a deionized water sonication bath. In one or more examples, such as for particle removal, the surfaces of the turbine engine component 300 can be exposed to sonication (e.g., megasonication) and/or a supercritical fluid (carbon dioxide, water, one or more alcohols) wash, followed by exposing to cycles of purge gas or liquid (e.g., N₂, Ar, He, one or more alcohols, H₂O, or any combination thereof) and vacuum purges to remove particles from and dry the surfaces. In some examples, the turbine engine component 300 can be exposed to heating or drying processes, such as heating the turbine engine component 300 to a temperature of about 50° C., about 65° C., or about 80° C. to about 100° C., about 120° C., or about 150° C. and exposing the surfaces to purge gas. The turbine engine component 300 can be heated in an oven or exposed to lamps for the heating or drying processes. Optionally, hot gas can be forced through internal passages to accelerate drying. Optionally, the turbine engine component 300 can be dried in reduced atmosphere without heating or with heating.

### Bond Coats

Referring to FIGS. 2 and 3B, the method 200 proceeds at block 204 by forming a bond coat 306 over the superalloy substrate 302. In some embodiments, the bond coat 306 may be optional. In some embodiments, the bond coat 306 may directly contact the surface 304, the first masked portion 304a, and/or the second treated portion 304b. The bond coat 306 may be formed using low pressure plasma spray, cathodic arc, EBPVD, electroplating with a platinum group metal, aluminizing, or combinations thereof. In some other embodiments, the bond coat 306 may be formed using high velocity oxy-fuel (HVOF), air plasma spray (APS), or combinations thereof. In some embodiments, the bond coat 306 may be annealed to enhance adhesion to the surface 304 and to enhance inter-diffusion. In some embodiments, annealing may include a temperature of about 500° C. or greater.

In some embodiments, the bond coat 306 may have a thickness T1 of from about 100 nm to about 50 μm, measured from an outer surface 308 of the bond coat 306 to the surface 304 of the superalloy substrate 302. In some embodiments, the thickness T1 of the bond coat 306 may be measured using weight gain, optical profilometry, stylus profilometry, other non-destructive methods, or combinations thereof. In some embodiments, cooling holes may be drilled in the bond coat 306.

The bond coat 306 can be or include MCrAl(X) where M is selected from Ni, Co, or combinations thereof and where X is selected from Hf, W, Zr, rare earth elements (e.g., Y or La), or combinations thereof. For example, the bond coat 306 can be or include NiCrAlY, NiCrAlHf, NiCrAlZr, NiCoCrAlY, NiCoCrAlYTa, or combinations thereof. In some embodiments, the bond coat 306 can be or include SiAl, PtAl, NiAl, modified NiAl including Pt, Rh, Pd, or combinations thereof. In some embodiments, the bond coat 306 can independently include Ni, Co, Cr, Al, Pt, Rh, Pd, Re, Hf, W, Zr, Ta, rare earth elements (e.g., Y or La), or combinations thereof.

Referring to FIGS. 2 and 3C, the method 200 proceeds at block 206 by masking a first portion 308a of the outer surface 308 to prevent an oxide layer 310 from being formed on the first portion 308a. In some embodiments, a mask 309 may be applied over the first portion 308a using CVD, PVD, EBPVD, or combinations thereof. In one or more embodiments, the mask 309 may be continuous and/or crack-free to block a gas phase of the oxide layer 310 from reaching the first portion 308a. In some embodiments, the mask 309 can be or include titanium nitride, zirconium nitride, hafnium nitride, calcium fluoride, strontium fluoride, barium fluoride, aluminum nitride, scandium oxide, zirconium oxide, hafnium oxide, other ceramic materials, other suitable materials, or combinations thereof. In some embodiments, the mask material may be stable at temperatures used for forming the oxide layer 310. In some embodiments, the mask material may not react with either the surface 308 or the gas phase of the oxide layer 310. In one or more embodiments, the mask 309 can be removed using mechanical abrasion (e.g., grit blasting) and/or chemical cleaning.

Referring to FIGS. 2 and 3D, the method 200 proceeds at block 208 by treating a second portion 308b of the outer surface 308 to prepare the second portion 308b for receiving an oxide layer 310. In some embodiments, the first and second portions 308a, 308b may be different portions of the outer surface 308. In some embodiments, the first and second portions 308a, 308b may overlap. In some embodiments, the outer surface 308 may be treated before the first portion 308a is masked. In one or more embodiments, only the second portion 308b may be treated after the first portion 308a is masked. In some embodiments, the outer surface 308 and/or the second portion 308b may be treated using wet cleaning, dry cleaning, oxide etching, grit blasting, polishing, or combinations thereof.

### Oxide Layers

Referring to FIGS. 2 and 3E, the method 200 proceeds at block 210 by depositing an oxide layer 310 over the bond coat 306. In some embodiments, the oxide layer 310 may directly contact the outer surface 308, the first masked portion 308a, and/or the second treated portion 308b. In some embodiments, the oxide layer 310 may be deposited using CVD, PVD, EBPVD, atomic layer deposition (ALD), or combinations thereof. In addition, the oxide layer 310 can be deposited using plasma-enhanced CVD (PE-CVD), pulsed-CVD, chemical vapor aluminization (CVA), reactive PVD, plasma-enhanced ALD (PE-ALD), or combinations thereof.

In one or more embodiments, depositing the oxide layer 310 can include sequentially exposing the bond coat 306 to an aluminum precursor and one or more reactants to form an aluminum-containing layer on the surface 308, such as by an ALD process. In some examples, the reactant can be or contain one or more oxidizing agents. The oxidizing agent can be or contain water, ozone, oxygen (O₂), atomic oxygen, nitrous oxide, one or more peroxides (e.g., hydrogen peroxide, other inorganic peroxides, organic peroxides), one or more alcohols (e.g., methanol, ethanol, propanol, or higher alcohols), plasmas thereof, or any combination thereof.

In other embodiments, an ALD process can be used to deposit an oxide layer 310 having a metal dopant. The metal dopant can be deposited by including the metal dopant during the ALD process. In some examples, the metal dopant can be included in a separate ALD cycle relative to the ALD cycles used to deposit the oxide material. In other examples, the metal dopant can be co-injected with the aluminum precursor used during the ALD cycle. In further examples, the metal dopant can be injected separately from the aluminum precursor during the ALD cycle. For example, one ALD cycle can include exposing the turbine engine component 300 to: the aluminum precursor, a pump-purge, the metal dopant, a pump-purge, the one or more reactants, and a pump-purge to form the oxide layer 310. In some examples, one ALD cycle can include exposing the turbine engine component 300 to: the metal dopant, a pump-purge, the aluminum precursor, a pump-purge, the one or more reactants, and a pump-purge to form the oxide layer 310. In other examples, one ALD cycle can include exposing the turbine engine component 300 to: the aluminum precursor, the metal dopant, a pump-purge, the one or more reactants, and a pump-purge to form the oxide layer 310.

In other embodiments, depositing the oxide layer 310 can include a CVD process where a method includes simultaneously exposing the turbine engine component 300 to the aluminum precursor and the one or more reactants to form the oxide layer 310. During an ALD process or a CVD process, each of the aluminum precursor and the one or more reactants can independently include one or more carrier gases. One or more purge gases can be flowed across the turbine engine component 300 and/or throughout the processing chamber in between the exposures of the aluminum precursor and the one or more reactants. In some examples, the same gas may be used as a carrier gas and a purge gas. Exemplary carrier gases and purge gases can independently be or include one or more of nitrogen (N₂), argon, helium, neon, hydrogen (H₂), or any combination thereof.

In one or more examples, the oxide layer 310 can be produced by delivering the aluminum precursor (e.g., at a temperature of about 0° C. to about 30° C.) to the turbine engine component 300 via vapor phase delivery for a pre-determined pulse length (e.g., about 0.1 seconds). During this process, the deposition reactor may be operated under a flow of nitrogen carrier gas (e.g., about 100 sccm total) with the chamber held at a pre-determined temperature (e.g., about 150° C. to about 350° C.) and pressure (e.g., about 1 Torr to about 5 Torr). After the pulse of aluminum precursor, the chamber may be subsequently pumped and purged of all requisite gases and byproducts for a determined amount of time. Subsequently, water vapor may be pulsed into the chamber for about 0.1 seconds at chamber pressure of about 3.5 Torr. An additional chamber purge may be performed to rid the reactor of any excess reactants and reaction byproducts. This process can be repeated as many times as necessary to get the target oxide layer 310 to the desired thickness. The turbine engine component 300 can be subjected to an annealing furnace at a temperature of about 500° C. under inert nitrogen flow of about 500 sccm for about one hour.

In one or more embodiments, a bulk temperature of each of the superalloy substrate 302 and the bond coat 306 during deposition of the oxide layer 310 may be less than or about 1,150° C., less than or about 1,100° C., less than or about 900° C., less than or about 700° C., less than or about 600° C., less than or about 500° C., less than or about 400° C., less than or about 350° C., less than or about 300° C., less than or about 250° C., less than or about 200° C., or less than or about 150° C.

In some embodiments, the oxide layer may be deposited at a chamber temperature of from about 23° C. to about 300° C. In some embodiments, the oxide layer may be deposited under vacuum conditions, such as at a chamber pressure of from about 1 mbar to about 100 mbar, alternatively less than about 1 mbar, such as from about 0.001 mbar to about 1 mbar.

Referring still to FIGS. 2 and 3E, the method 200 proceeds at block 212 by measuring a thickness T2 of the oxide layer 310, where the thickness T2 is measured from an outer surface 312 of the oxide layer 310 to the outer surface 308 of the bond coat 306. In some embodiments, the thickness T2 of the oxide layer 310 may be measured using ellipsometry, eddy current, weight gain, other non-destructive methods, or combinations thereof.

In some embodiments, the thickness T2 may be about 3 μm or less, such as about 2.5 μm or less, such as about 2 μm or less, such as about 1.5 μm or less, such as about 1.4 μm or less, such as about 1.3 μm or less, such as about 1.2 μm or less, such as about 1.1 μm or less, such as about 1 μm or less, such as about 900 nm or less, such as about 800 nm or less, such as about 700 nm or less, such as about 600 nm or less, such as about 500 nm or less, such as about 400 nm or less, such as about 300 nm or less, such as about 200 nm or less, such as about 100 nm or less. In one or more embodiments, the thickness T2 may be from about 100 nm to about 3 μm, such as from about 100 nm to about 2.5 μm, such as from about 100 nm to about 2 μm, such as from about 100 nm to about 1.5 μm, such as from about 100 nm to about 1.4 μm, such as from about 100 nm to about 1.3 μm, such as from about 100 nm to about 1.2 μm, such as from about 100 nm to about 1.1 μm, such as from about 100 nm to about 1 μm, such as from about 100 nm to about 900 nm, such as from about 100 nm to about 800 nm, such as from about 100 nm to about 700 nm, such as from about 100 nm to about 600 nm, such as from about 100 nm to about 500 nm, such as from about 100 nm to about 400 nm, such as from about 100 nm to about 300 nm, such as from about 100 nm to about 200 nm, such as about 100 nm.

In one or more embodiments, a variation of the thickness T2 can be less than 500%, such as less than or about 400%, less than or about 300%, less than or about 200%, less than or about 150%, less than or about 100%, less than or about 50%, less than or about 20%, less than or about 18%, less than or about 15%, less than or about 12%, less than or about 10%, less than or about 8%, less than or about 6%, less than or about 5%, less than or about 4%, less than or about 3%, less than or about 2%, or less than or about 1%.

Referring to FIGS. 2 and 3F, the method 200 proceeds at block 214 by annealing the oxide layer 310 to increase an α-Al₂O₃ phase fraction of the oxide layer 310. In some embodiments, annealing may include thermal annealing, radiative heating, laser annealing, plasma annealing, light annealing, or combinations thereof. In some embodiments, annealing may include heating the oxide layer 310 to a temperature of about 400° C. or greater, such as from about 400° C. to about 1,200° C., such as from about 400° C. to about 1,000° C., such as from about 400° C. to about 800° C., such as from about 400° C. to about 600° C., alternatively a temperature of about 500° C. or greater, such as from about 500° C. to about 1,200° C., such as from about 500° C. to about 1,100° C., such as from about 500° C. to about 1,000° C., such as from about 500° C. to about 900° C., such as from about 500° C. to about 800° C., such as from about 500° C. to about 700° C., such as from about 500° C. to about 600° C., alternatively a temperature of about 700° C. or greater, such as from about 700° C. to about 1,200° C., such as from about 700° C. to about 1,100° C., such as from about 700° C. to about 1,000° C., such as from about 700° C. to about 900° C., such as from about 700° C. to about 800° C.

The turbine engine component 300 can be under a vacuum at a low pressure (e.g., from about 0.1 Torr to less than 760 Torr), at ambient pressure (e.g., about 760 Torr), and/or at a high pressure (e.g., from greater than 760 Torr (1 atm) to about 3,678 Torr (about 5 atm)) during the annealing process. The turbine engine component 300 can be exposed to an atmosphere containing one or more gases during the annealing process. Exemplary gases used during the annealing process can be or include nitrogen (N₂), argon, helium, hydrogen (H₂), oxygen (02), or any combinations thereof. The annealing process can be performed for about 0.01 seconds to about 10 minutes. In some examples, the annealing process can be a thermal anneal and lasts for about 1 minute, about 5 minutes, about 10 minutes, or about 30 minutes to about 1 hour, about 2 hours, about 5 hours, or about 24 hours. In other examples, the annealing process can be a laser anneal or a spike anneal and lasts for about 1 millisecond, about 100 millisecond, or about 1 second to about 5 seconds, about 10 seconds, or about 15 seconds.

In some embodiments, the oxide layer 310 can be or include monolayer films, multi-layer films, nanolaminate film stacks, coalesced films, crystalline films, or combinations thereof.

Al₂O₃

In some embodiments, the oxide layer 310 can be or include an aluminum (III) oxide (Al₂O₃). In some embodiments, an Al₂O₃ is about 95 wt % or greater, such as about 99 wt % or greater, such as about 99.9 wt % or greater, such as about 99.99 wt % or greater, such as about 99.999 wt % or greater such as about 99.9999 wt % or greater, based on total weight of the oxide layer 310. For example, the Al₂O₃ may be from about 95 wt % to about 99 wt %, alternatively from about 99 wt % to about 99.9 wt %, alternatively from about 99.9 wt % to about 99.99 wt %, alternatively from about 99.99 wt % to about 99.999 wt %, alternatively from about 99.999 wt % to about 99.9999 wt %, based on total weight of the oxide layer 310. In one or more embodiments, the oxide layer 310 may be pure Al₂O₃ without metal dopants and/or impurities. In some embodiments, the oxide layer 310 may be defect-free. In some embodiments, the oxide layer 310 may include a metal dopant, non-metal impurities and/or metal impurities.

In some embodiments, the Al₂O₃ can be or include crystalline, octahedral α-Al₂O₃, which is thermodynamically stable. In some embodiments, the Al₂O₃ can include one or more of metastable phases, including without limitation a cubic γ, a cubic η phase, a monoclinic θ phase, a hexagonal χ phase, an orthorhombic κ phase, a tetragonal or orthorhombic δ phase, or combinations thereof.

In some embodiments, the Al₂O₃ contains a crystalline structure, a polycrystalline structure, an amorphous structure, or combinations thereof. In some embodiments, the Al₂O₃ contains a primary phase and one or more secondary phases. In some embodiments, the primary phase contains α-Al₂O₃, and the one or more secondary phases are selected from γ-Al₂O₃, η-Al₂O₃, θ-Al₂O₃, χ-Al₂O₃, κ-Al₂O₃, δ-Al₂O₃, or combinations thereof.

In some embodiments, the Al₂O₃ has an α-Al₂O₃ phase fraction of about 50% or greater, such as about 60% or greater, such as about 70% or greater, such as about 80% or greater, such as about 90% or greater, such as about 95% or greater, such as about 99% or greater, such as about 99.9% or greater, such as about 99.99% or greater, such as about 99.999% or greater, such as about 99.9999% or greater, alternatively from about 99% to about 99.9999%, such as from about 99% to about 99.999%, such as from about 99% to about 99.99% such as from about 99% to about 99.9%.

In some embodiments, the Al₂O₃ has a γ-Al₂O₃ phase fraction and/or another secondary phase fraction of about 50% or less, such as about 40% or less, such as about 30% or less, such as about 20% or less, such as about 10% or less, such as about 5% or less, such as about 1% or less, such as about 0.1% or less, such as about 0.01% or less, such as about 0.001% or less, such as about 0.0001% or less. For example, a γ-Al₂O₃ phase fraction and/or another secondary phase fraction may be from about 0% to about 50%, such as from about 0.0001% to about 40%, such as from about 0.0001% to about 30%, such as from about 0.0001% to about 20%, such as from about 0.0001% to about 10%, such as from about 0.0001% to about 5%, such as from about 0.0001% to about 1%, such as from about 0.0001% to about 0.1%, such as from about 0.0001% to about 0.01%, such as from about 0.0001% to about 0.001%, alternatively from about 0.001% to about 0.01%, alternatively from about 0.01% to about 0.1%, alternatively from about 0.1% to about 1%, alternatively from about 1% to about 5%, alternatively from about 5% to about 10%, alternatively from about 10% to about 20%, alternatively from about 20% to about 30%, alternatively from about 30% to about 40%, alternatively from about 40% to about 50%.

In some embodiments, a ratio of a density of the oxide layer 310 to a theoretical density of α-Al₂O₃ is about 90% or greater, such as about 95% or greater, such as about 99% or greater, such as about 99.9% or greater, such as about 99.99% or greater, such as from about 99.99% to about 100%, alternatively from about 95% to about 99%, alternatively from about 99% to about 99.9%, alternatively from about 99.9% to about 99.99%.

In some embodiments, the outer surface 312 of the oxide layer 310 has a roughness value (Ra) of from about 1 μm to about 100 μm, such as from about 1 μm to about 10 μm, alternatively from about 10 μm to about 20 μm, alternatively from about 20 μm to about 30 μm, alternatively from about 30 μm to about 40 μm, alternatively from about 40 μm to about 50 μm, alternatively from about 50 μm to about 60 μm, alternatively from about 60 μm to about 70 μm, alternatively from about 70 μm to about 80 μm, alternatively from about 80 μm to about 90 μm, alternatively from about 90 μm to about 100 μm.

In some embodiments, a parabolic oxidation constant of a superalloy substrate 302 having an oxide layer 310 of the present disclosure is about 0.4×10⁻³ mg²/cm⁴/cycle or less, such as about 0.3×10⁻³ mg²/cm⁴/cycle or less, such as about 0.2×10⁻³ mg²/cm⁴/cycle or less, such as about 0.1×10⁻³ mg²/cm⁴/cycle or less, where each cycle includes heating at about 1100° C. for about 45 min. For example, a parabolic oxidation constant of a superalloy substrate 302 having an oxide layer 310 of the present disclosure is from about 0.01×10⁻³ mg²/cm⁴/cycle to about 0.1×10⁻³ mg²/cm⁴/cycle, alternatively from about 0.1×10⁻³ mg²/cm⁴/cycle to about 0.2×10⁻³ mg²/cm⁴/cycle, alternatively from about 0.2×10⁻³ mg²/cm⁴/cycle to about 0.3×10⁻³ mg²/cm⁴/cycle, alternatively from about 0.3×10⁻³ mg²/cm⁴/cycle to about 0.4×10⁻³ mg²/cm⁴/cycle, where each cycle includes heating at about 1100° C. for about 45 min.

In some embodiments, a ratio of a parabolic oxidation constant of a superalloy substrate 302 having an oxide layer 310 of the present disclosure relative to a parabolic oxidation constant of the superalloy substrate 302 without the oxide layer 310 is about 50% or less, such as about 33% or less, such as about 25% or less, such as about 20% or less, such as about 15% or less, such as about 10% or less, such as about 5% or less. For example, the ratio of a parabolic oxidation constant of a superalloy substrate 302 having an oxide layer 310 to a parabolic oxidation constant of the superalloy substrate 302 without the oxide layer 310 can be from about 1% to about 5%, alternatively from about 5% to about 10%, alternatively from about 10% to about 15%, alternatively from about 15% to about 20%, alternatively from about 20% to about 25%, alternatively from about 25% to about 30%, alternatively from about 30% to about 40%, alternatively from about 40% to about 50%.

### Metal Dopant

In some embodiments, the oxide layer 310 can include a metal dopant. In some embodiments, the metal dopant is about 10 wt % or less, such as about 5 wt % or less, such as about 1 wt % or less, such as about 0.1 wt % or less, such as about 0.01 wt % or less, based on total weight of the oxide layer 310. For example, the metal dopant may be from about 0.01 wt % to about 10 wt %, such as from about 0.01 wt % to about 0.1 wt %, alternatively from about 0.1 wt % to about 1 wt %, alternatively from about 1 wt % to about 2 wt %, alternatively from about 2 wt % to about 3 wt %, alternatively from about 3 wt % to about 4 wt %, alternatively from about 4 wt % to about 5 wt %, alternatively from about 5 wt % to about 6 wt %, alternatively from about 6 wt % to about 7 wt %, alternatively from about 7 wt % to about 8 wt %, alternatively from about 8 wt % to about 9 wt %, alternatively from about 9 wt % to about 10 wt %, based on total weight of the oxide layer 310.

In some embodiments, the metal dopant is selected from Hf, Y, La, Ce, Cr, Nd, Dy, Yb, Sr, Ba, Lu, Ho, Gd, Er, Ti, Nb, Sm, Tb, Tm, oxides thereof, or combinations thereof. In one or more embodiments, the metal dopant is a rare-earth metal. In some embodiments, the metal dopant is any La-group metal.

In some embodiments, the metal dopant is present only in the α-Al₂O₃ phase and/or along grain boundaries between phases. In some embodiments, one or more secondary phases are free of the metal dopant. In one or more other embodiments, the metal dopant may also be present in one or more secondary phases.

In some embodiments, a fraction of the metal dopant in the α-Al₂O₃ phase is about 95 wt % or greater, such as about 99 wt % or greater, such as about 99.9 wt % or greater, such as about 99.99 wt % or greater, such as about 100 wt %, based on total weight of the metal dopant. For example, a fraction of the metal dopant in the α-Al₂O₃ phase is from about 95 wt % to about 100 wt %, such as from about 99 wt % to about 99.99 wt %, such as from about 99.9 wt % to about 99.99 wt %, based on total weight of the metal dopant.

In some embodiments, a fraction of the metal dopant in the one or more secondary phases is about 5 wt % or less, such as from about 1 wt % or less, such as about 0.1 wt % or less, such as about 0.01 wt % or less, such as about 0 wt %, based on total weight of the metal dopant. For example, a fraction of the metal dopant in the one or more secondary phases is from about 0 wt % to about 5 wt %, such as from about 0.01 wt % to about 1 wt %, such as about 0.01 wt % to about 0.1 wt %, based on total weight of the metal dopant.

### Non-Metal Impurities

In some embodiments, the oxide layer 310 includes a non-metal impurity selected from sulfur, carbon, nitrogen, or combinations thereof. In some embodiments, a concentration of the non-metal impurity is about 5 wt % or less, such as about 1 wt % or less, such as about 0.1 wt % or less, such as about 0.01 wt % or less, such as about 0 wt %, based on total weight of the oxide layer 310. For example, the non-metal impurity may have a concentration of from about 0 wt % to about 5 wt %, such as from about 0 wt % to about 1 wt %, such as from about 0 wt % to about 0.1 wt %, such as from about 0 wt % to about 0.01 wt %, alternatively from about 0.01 wt % to about 5 wt %, such as from about 0.01 wt % to about 1 wt %, such as from about 0.01 wt % to about 0.1 wt %, alternatively from about 0.1 wt % to about 5 wt %, such as from about 0.1 wt % to about 1 wt %, alternatively from about 1 wt % to about 5 wt %, based on total weight of the oxide layer 310.

### Metal Impurities

In some embodiments, the oxide layer 310 includes a metal impurity selected from oxides of nickel, cobalt, tantalum, or combinations thereof. In some embodiments, a concentration of the metal impurity is about 5 wt % or less, such as about 1 wt % or less, such as about 0.1 wt % or less, such as about 0.01 wt % or less, such as about 0 wt %, based on total weight of the oxide layer 310. For example, the metal impurity may have a concentration of from about 0 wt % to about 5 wt %, such as from about 0 wt % to about 1 wt %, such as from about 0 wt % to about 0.1 wt %, such as from about 0 wt % to about 0.01 wt %, alternatively from about 0.01 wt % to about 5 wt %, such as from about 0.01 wt % to about 1 wt %, such as from about 0.01 wt % to about 0.1 wt %, alternatively from about 0.1 wt % to about 5 wt %, such as from about 0.1 wt % to about 1 wt %, alternatively from about 1 wt % to about 5 wt %, based on total weight of the oxide layer 310.

### Thermal Barrier Coatings

Referring to FIGS. 2 and 3G, the method 200 proceeds at block 216 by forming a thermal barrier coating (TBC) 314 over the oxide layer 310. In some embodiments, the TBC 314 may directly contact the outer surface 312 of the oxide layer. Exemplary processes which may be used to form the TBC 314 include EBPVD, thermal spray, plasma spray, suspension plasma spray, sol-gel, or combinations thereof. In one or more embodiments, the TBC 314 may have a thickness T3 of from about 100 nm to about 300 μm, measured from an outer surface 316 of the TBC 314 to the outer surface 312 of the oxide layer 310. In some embodiments, the thickness T3 of the TBC 314 may be measured using weight gain, eddy current, optical profilometry, stylus profilometry, other non-destructive methods, or combinations thereof. In some embodiments, cooling holes may be drilled in the TBC 314.

TBCs of the present disclosure can be or include yttria-stabilized zirconia (YSZ), such as 7 wt % yttria-stabilized zirconia (7-YSZ), 8 wt % yttria-stabilized zirconia (8-YSZ), and other YSZ formulations, M₂Zr₂O₇ where M is a rare-earth metal selected from La, Ce, Pr, Nd, Pm, Sm, Eu, and Gd, SrZrO₃, other ceramics, or combinations thereof.

Embodiments of the present disclosure further relate to any one or more of the following paragraphs 1-29:

1. An oxide layer comprising: aluminum oxide; and a metal dopant.

2. A turbine engine component, comprising: a superalloy substrate; a bond coat disposed over the superalloy substrate; an oxide layer of paragraph 1 disposed over the bond coat; and a thermal barrier coating disposed over the oxide layer.

3. The turbine engine component according to any one of paragraphs 1-2, wherein the oxide layer comprises about 95 wt % or greater of the aluminum oxide, based on total weight of the oxide layer.

4. The turbine engine component according to any one of paragraphs 1-3, wherein about 99% or greater of the aluminum oxide comprises a crystalline structure having an α-Al₂O₃ phase.

5. The turbine engine component according to any one of paragraphs 1-4, wherein about 1% or less of the aluminum oxide comprises a γ-Al₂O₃ phase.

6. The turbine engine component according to any one of paragraphs 1-5, wherein the oxide layer comprises about 10 wt % or less of the metal dopant, based on total weight of the oxide layer.

7. The turbine engine component according to any one of paragraphs 1-6, wherein the metal dopant is selected from Hf, Y, La, Ce, Cr, Nd, Dy, Yb, Sr, Ba, Lu, Ho, Gd, Er, Ti, Nb, Sm, Tb, Tm, or combinations thereof.

8. The turbine engine component according to any one of paragraphs 1-7, wherein the metal dopant is a rare-earth metal.

9. The turbine engine component according to any one of paragraphs 1-8, wherein the oxide layer comprises an α-Al₂O₃ phase, and wherein about 99 wt % or greater of the metal dopant is in the α-Al₂O₃ phase.

10. The turbine engine component according to any one of paragraphs 1-9, wherein the oxide layer comprises a primary α-Al₂O₃ phase and a secondary γ-Al₂O₃ phase, and wherein about 1 wt % or less of the metal dopant is in the γ-Al₂O₃ phase.

11. The turbine engine component according to any one of paragraphs 1-10, wherein a fraction of the metal dopant content in the primary α-Al₂O₃ phase and along grain boundaries between phases is about 99.9 wt % or greater, based on total weight of the metal dopant content.

12. The turbine engine component according to any one of paragraphs 1-11, wherein a thickness of the oxide layer is about 3 μm or less.

13. The turbine engine component according to any one of paragraphs 1-12, wherein a density of the oxide layer is about 90% or greater of a theoretical density of α-Al₂O₃.

14. The turbine engine component according to any one of paragraphs 1-13, wherein the oxide layer has a top surface contacting the thermal barrier coating, and wherein a roughness value (Ra) of the top surface is from about 1 μm to about 100 μm.

15. The turbine engine component according to any one of paragraphs 1-14, wherein the oxide layer comprises about 5 wt % or less of a non-metal impurity, based on total weight of the oxide layer, and wherein the non-metal impurity is selected from sulfur, carbon, nitrogen, or combinations thereof.

16. The turbine engine component according to any one of paragraphs 1-15, wherein the oxide layer comprises about 5 wt % or less of a metal impurity, based on total weight of the oxide layer, and wherein the metal impurity is selected from oxides of nickel, cobalt, tantalum, or combinations thereof.

17. The turbine engine component according to any one of paragraphs 1-16, wherein the superalloy substrate comprises at least one of nickel, cobalt, iron, chromium, or combinations thereof, wherein a parabolic oxidation constant of the turbine engine component is about 0.4×10⁻³ mg²/cm⁴/cycle or less, and wherein each cycle comprises heating at 1100° C. for 45 min.

18. The turbine engine component according to any one of paragraphs 1-17, wherein the parabolic oxidation constant of the turbine engine component is about ⅓ or less compared to the parabolic oxidation constant of a control substrate without the oxide layer.

19. A method for coating a superalloy substrate of a turbine engine component, comprising: forming a bond coat over the superalloy substrate; depositing an oxide layer over the bond coat using at least one of chemical vapor deposition (CVD), physical vapor deposition (PVD), atomic layer deposition (ALD), or combinations thereof; and forming a thermal barrier coating over the oxide layer.

20. The method according to paragraph 19, wherein the oxide layer comprises: aluminum oxide; and a metal dopant.

21. The method according to any one of paragraphs 19-20, further comprising, before depositing the oxide layer, treating at least a portion of the bond coat using at least one of wet cleaning, dry cleaning, oxide etching, grit blasting, polishing, or combinations thereof.

22. The method according to any one of paragraphs 19-21, further comprising, before depositing the oxide layer, masking at least a portion of the bond coat.

23. The method according to any one of paragraphs 19-22, further comprising measuring a thickness of the oxide layer using at least one of ellipsometry, eddy current, weight gain, or combinations thereof.

24. The method according to any one of paragraphs 19-23, further comprising annealing the oxide layer by at least one of thermal annealing, radiative heating, laser annealing, or combinations thereof, wherein annealing the oxide layer increases an α-Al₂O₃ phase fraction of the aluminum oxide to about 99% or greater.

25. The method according to any one of paragraphs 19-24, wherein forming the bond coat comprises using at least one of low pressure plasma spray, cathodic arc, electron beam PVD (EBPVD), electroplating with a platinum group metal, aluminizing, or combinations thereof.

26. The method according to any one of paragraphs 19-25, wherein forming the thermal barrier coating comprises using at least one of EBPVD, thermal spray, plasma spray, suspension plasma spray, sol-gel, or combinations thereof.

27. A turbine engine component prepared by the method according to any one of paragraphs 19-26.

28. A turbine engine component, comprising: a superalloy substrate including at least one of a nickel-based superalloy, a cobalt-based superalloy, an iron-based superalloy, or a combination thereof; a bond coat contacting the superalloy substrate, the bond coat including at least one metal having the formula MCrAl(X), wherein M is selected from the group consisting of Ni and Co, and wherein X is selected from the group consisting of Hf, W, Zr, Y, and La; an oxide layer contacting the bond coat, wherein the oxide layer comprises: aluminum oxide, wherein the oxide layer includes about 95 wt % or greater of the aluminum oxide, based on total weight of the oxide layer; and a metal dopant, wherein the metal dopant is selected from the group consisting of Hf, Y, La, Ce, Cr, Nd, Dy, Yb, Sr, Ba, Lu, Ho, Gd, Er, Ti, Nb, Sm, Tb, and Tm; and a thermal barrier coating contacting the oxide layer.

29. The turbine engine component of paragraph 28, wherein about 99% or greater of the aluminum oxide has a crystalline α-Al2O3 phase.

While the foregoing is directed to embodiments of the disclosure, other and further embodiments may be devised without departing from the basic scope thereof, and the scope thereof is determined by the claims that follow. All documents described herein are incorporated by reference herein, including any priority documents and/or testing procedures to the extent they are not inconsistent with this text. As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term “comprising” is considered synonymous with the term “including” for purposes of United States law. Likewise whenever a composition, an element or a group of elements is preceded with the transitional phrase “comprising”, it is understood that we also contemplate the same composition or group of elements with transitional phrases “consisting essentially of,” “consisting of”, “selected from the group of consisting of,” or “is” preceding the recitation of the composition, element, or elements and vice versa.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below.

What is claimed is:

1. A turbine engine component, comprising:
a superalloy substrate;
a bond coat disposed over the superalloy substrate;
an oxide layer disposed over the bond coat, wherein the oxide layer comprises:
aluminum oxide; and
a metal dopant; and
a thermal barrier coating disposed over the oxide layer.

2. The turbine engine component of claim 1, wherein the oxide layer comprises about 95 wt % or greater of the aluminum oxide, based on total weight of the oxide layer.

3. The turbine engine component of claim 1, wherein about 99% or greater of the aluminum oxide comprises a crystalline structure having an α-Al₂O₃ phase.

4. The turbine engine component of claim 1, wherein about 1% or less of the aluminum oxide comprises a γ-Al₂O₃ phase.

5. The turbine engine component of claim 1, wherein the oxide layer comprises about 10 wt % or less of the metal dopant, based on total weight of the oxide layer.

6. The turbine engine component of claim 1, wherein the metal dopant is selected from Hf, Y, La, Ce, Cr, Nd, Dy, Yb, Sr, Ba, Lu, Ho, Gd, Er, Ti, Nb, Sm, Tb, Tm, or combinations thereof.

7. The turbine engine component of claim 1, wherein the metal dopant is a rare-earth metal.

8. The turbine engine component of claim 1, wherein the oxide layer comprises an α-Al₂O₃ phase, and wherein about 99 wt % or greater of the metal dopant is in the α-Al₂O₃ phase.

9. The turbine engine component of claim 1, wherein the oxide layer comprises a primary α-Al₂O₃ phase and a secondary γ-Al₂O₃ phase, and wherein about 1 wt % or less of the metal dopant is in the γ-Al₂O₃ phase.

10. The turbine engine component of claim 9, wherein about 99 wt % or greater of the metal dopant is in the primary α-Al₂O₃ phase or along grain boundaries between phases.

11. The turbine engine component of claim 1, wherein a density of the oxide layer is about 90% or greater of a theoretical density of α-Al₂O₃.

12. The turbine engine component of claim 1, wherein the oxide layer comprises about 5 wt % or less of a non-metal impurity, based on total weight of the oxide layer, and wherein the non-metal impurity is selected from sulfur, carbon, nitrogen, or combinations thereof.

13. The turbine engine component of claim 1, wherein the oxide layer comprises about 5 wt % or less of a metal impurity, based on total weight of the oxide layer, and wherein the metal impurity is selected from oxides of nickel, cobalt, tantalum, or combinations thereof.

14. A method for coating a superalloy substrate of a turbine engine component, comprising:
forming a bond coat over the superalloy substrate;
depositing an oxide layer over the bond coat using at least one of chemical vapor deposition (CVD), physical vapor deposition (PVD), atomic layer deposition (ALD), or combinations thereof, wherein the oxide layer comprises:
aluminum oxide; and
a metal dopant; and
forming a thermal barrier coating over the oxide layer.

15. The method of claim 14, further comprising, before depositing the oxide layer, treating at least a portion of the bond coat using at least one of wet cleaning, dry cleaning, oxide etching, grit blasting, polishing, or combinations thereof.

16. The method of claim 14, further comprising, before depositing the oxide layer, masking at least a portion of the bond coat.

17. The method of claim 14, further comprising measuring a thickness of the oxide layer using at least one of ellipsometry, eddy current, weight gain, or combinations thereof.

18. The method of claim 14, further comprising annealing the oxide layer by at least one of thermal annealing, radiative heating, laser annealing, or combinations thereof, wherein annealing the oxide layer increases an α-Al₂O₃ phase fraction of the aluminum oxide to about 99% or greater.

19. A turbine engine component, comprising:
a superalloy substrate including at least one of a nickel-based superalloy, a cobalt-based superalloy, an iron-based superalloy, or a combination thereof;
a bond coat contacting the superalloy substrate, the bond coat including at least one metal having the formula MCrAl(X), wherein M is selected from the group consisting of Ni and Co, and wherein X is selected from the group consisting of Hf, W, Zr, Y, and La;
an oxide layer contacting the bond coat, wherein the oxide layer comprises:
aluminum oxide, wherein the oxide layer includes about 95 wt % or greater of the aluminum oxide, based on total weight of the oxide layer; and
a metal dopant, wherein the metal dopant is selected from the group consisting of Hf, Y, La, Ce, Cr, Nd, Dy, Yb, Sr, Ba, Lu, Ho, Gd, Er, Ti, Nb, Sm, Tb, and Tm; and
a thermal barrier coating contacting the oxide layer.

20. The turbine engine component of claim 19, wherein about 99% or greater of the aluminum oxide has a crystalline α-Al₂O₃ phase.
